(19) United States
(12) Patent Application Publication
(10) Pub. No.: US 2024/0114811 A1
(43) Pub. Date: Apr. 4, 2024

(54) NONVOLATILE SEMICONDUCTOR MEMORY

(71) Applicant: Kioxia Corporation, Tokyo (JP)

(72) Inventors: Jieqiong ZHANG, Chiyoda Tokyo (JP); Katsuyoshi KOMATSU, Yokkaichi Mie (JP); Tadaomi DAIBOU, Yokkaichi Mie (JP); Yosuke MATSUSHIMA, Yokkaichi Mie (JP)

(21) Appl. No.: 18/460,515

(22) Filed: Sep. 1, 2023

(30) Foreign Application Priority Data
Oct. 4, 2022 (JP) 2022-160492

(51) Int. Cl. H10N 70/00; H10B 63/00; H10B 63/10

(52) U.S. Cl. CPC H10N 70/841; H10B 63/10; H10B 63/84; H10N 70/881

(57) ABSTRACT

According to one embodiment, a nonvolatile semiconductor memory includes a first electrode and a second electrode spaced from the first electrode. A memory element and a switching element are disposed between the first electrode and the second electrode. The switching element includes a tunnel insulating film enabling carrier tunneling, and the tunnel insulating film includes yttrium and oxygen and at least one of tantalum, titanium, and zirconium Ti, and Zr.

### CROSS-REFERENCE TO RELATED APPLICATION(S)

This application is based upon and claims the benefit of priority from Japanese Patent Application No. 2022-160492, filed Oct. 4, 2022, the entire contents of which are incorporated herein by reference.

### FIELD

Embodiments described herein relate generally to a nonvolatile semiconductor memory.

### BACKGROUND

In recent years, a resistive random access memory (ReRAM) utilizing a change in film resistance has been developed. As one type of the ReRAM, a phase-change memory (PCM) has been developed that utilizes a change in resistance value due to a thermal phase change between a crystalline state and an amorphous state in a storage region of a film. A selector applied for a nonvolatile semiconductor memory is required to have write resistance.

### BRIEF DESCRIPTION OF THE DRAWINGS

FIG. 1 is a schematic cross-sectional view of a nonvolatile semiconductor memory according to an embodiment.

FIG. 2 is a diagram illustrating barrier heights of tunnel insulating films according to a first embodiment.

FIG. 3 is a band diagram illustrating aspects related to an operating principle of a tunnel insulating films.

FIG. 4 is a schematic perspective view illustrating a configuration of tunnel insulating films according to a modification of a first embodiment.

FIG. 5 is a diagram illustrating barrier heights of tunnel insulating films according to the modification of a first embodiment.

FIG. 6 is a schematic perspective view illustrating a configuration of a nonvolatile semiconductor memory device including a nonvolatile semiconductor memory according to an embodiment.

FIG. 7 is a diagram illustrating a circuit configuration of a nonvolatile semiconductor memory device including a nonvolatile semiconductor memory according to an embodiment.

### DETAILED DESCRIPTION

Embodiments describe a nonvolatile semiconductor memory including, as a selector, a switching element enabling carrier tunneling while improving insulation (isolation) characteristics.

In general, according to one embodiment, a nonvolatile semiconductor memory includes a first electrode and a second electrode spaced from the first electrode. A memory element and a switching element are disposed between the first electrode and the second electrode. The switching element includes a tunnel insulating film that includes yttrium and oxygen along with at least one of tantalum, titanium, and zirconium.

Hereinafter, certain example embodiments will be described with reference to the drawings. The drawings are schematic. It is noted that in the following description, the same or substantially similar components, elements, aspects or the like are denoted by the same reference symbols, and description of components, elements, aspects or the like once described may be omitted as appropriate from subsequent description.

Qualitative analysis and quantitative analysis can be performed on a chemical composition of components or regions forming a nonvolatile semiconductor memory as described in this specification, using secondary ion mass spectroscopy (SIMS) or energy dispersive X-ray spectroscopy (EDX), for example. The thickness of the components or regions forming the nonvolatile semiconductor memory, the distance between the components or regions, and the like can be measured using a scanning electron microscope (SEM) or a transmission electron microscope (TEM), for example. Identification of crystal types or states of the components or regions forming a nonvolatile semiconductor memory and comparisons to determine which of the crystal types/states has a higher abundance can be performed using electron diffraction, for example.

### EMBODIMENTS

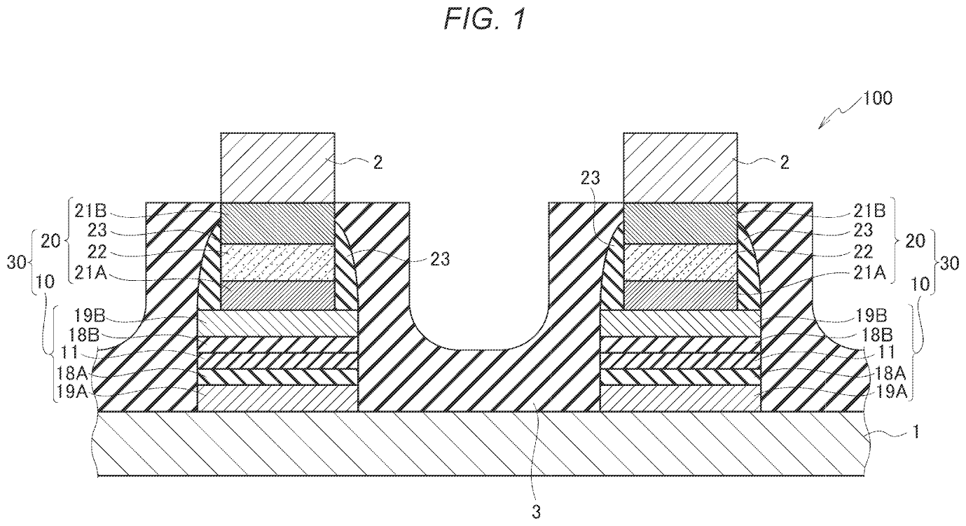

As illustrated in FIG. 1, a nonvolatile semiconductor memory 100 according to an embodiment includes a first electrode 1, second electrodes 2 disposed opposite to the first electrode 1, as well as memory elements 20 and switching elements 10 between the first electrode 1 and the second electrodes 2. Each switching element 10 includes tunnel insulating films (11, 18A, 18B) enabling carrier tunneling. It is noted that an interlayer insulating film 3 may be provided. In the following description, the switching element 10 and the memory element may be collectively referred to as a memory cell 30.

The first electrode 1 may be used as a word line, for example. The second electrode 2 may be used as a bit line, for example.

The memory element 20 includes memory element electrodes (21A, 21B), a memory layer 22, and a memory element insulating film 23. The memory element 20 is disposed on the switching element 10. The memory element 20 can be any of a resistive random access memory (ReRAM), a phase-change memory (PCM), a ferroelectric random access memory (FeRAM), or the like types. The memory element 20 can be a magneto tunnel junction (MTJ) variable resistance element.

The following description describes a nonvolatile semiconductor memory 100 including the switching element 10 serving as the selector.

### First Embodiment

### Configuration of Switching Element

The switching element 10 includes the tunnel insulating films (11, 18A, 18B) and switching element electrodes (19A, 19B).

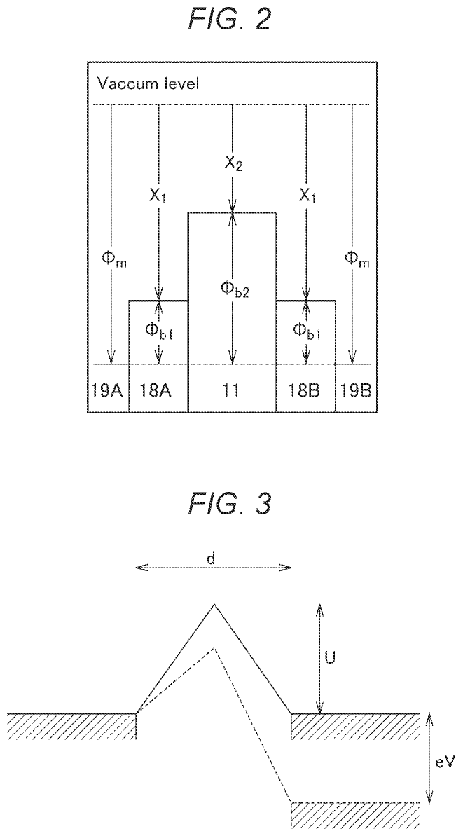

The tunnel insulating films (11, 18A, 18B) include a first insulating film 11 and second insulating films (18A, 18B). It is noted that the first insulating film 11 may itself be a single layer or a plurality of layers. 1 depicts the first insulating film 11 as a single layer. The composition and operating principle of the tunnel insulating films (11, 18A, 18B) will be described with reference to FIG. 2 and FIG. 3.

The lower side of the switching element electrode 19A is disposed on the first electrode 1.

The lower side of the switching element electrode 19B is disposed on the tunnel insulating films (11, 18A, 18B). Specifically, the lower side of the switching element electrode 19B is disposed on the second insulating film 18B.

### Composition of Switching Element

The tunnel insulating films (11, 18A, 18B) comprise, for example, oxygen and at least one of tantalum (Ta), titanium (Ti), and zirconium (Zr). The tunnel insulating films (11, 18A, 18B) also include yttrium (Y).

Specifically, for example, yttrium oxide (Y₂O₃) mixed with tantalum pentoxide (Ta₂O₅), titanium oxide (TiO₂), and/or zirconium oxide (ZrO₂) can be used as the material of the first insulating film 11.

The nonvolatile semiconductor memory 100 may include in at least one of the first insulating film 11 or the second insulating films (18A, 18B) Ta, O, and Y. In some examples, at least one element selected from a group consisting of hafnium (Hf), zirconium (Zr), scandium (Sc), niobium (Nb), and any member of the lanthanoid group may be included in at least one of the first insulating film 11 or the second insulating films (18A, 18B). The lanthanoid group includes: lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), and lutetium (Lu)).

Specifically, in a case where Y₂O₃ is mixed with Ta₂O₅ in the first insulating film 11, one or more layers of the switching element 10 may comprise at least one element selected from the group consisting of Hf, Zr, Sc, Nb, La, Ce, Pr, Nd, Pm, Sm, Eu, Gd, Tb, Dy, Ho, Er, Tm, Yb, Lu.

In the nonvolatile semiconductor memory 100, at least one of the first insulating film 11 and the second insulating films (18A, 18B) may comprise Ti, O, and Y and/or at least one element selected from the group consisting of lanthanoids (La, Ce, Pr, Nd, Pm, Sm, Eu, Gd, Tb, Dy, Ho, Er, Tm, Yb, Lu), Hf, Zr, and Sc. Specifically, in a case where Y₂O₃ is mixed with TiO₂ in the first insulating film 11, at least one layer of the switching element 10 may further include at least one element selected from the group consisting of lanthanoids (La, Ce, Pr, Nd, Pm, Sm, Eu, Gd, Tb, Dy, Ho, Er, Tm, Yb, Lu), Hf, Zr, and Sc.

In the nonvolatile semiconductor memory 100, at least one of the first insulating film 11 and the second insulating films (18A, 18B) of the switching element 10 may comprise Zr, O, and Y and/or at least one element selected from the group consisting of lanthanoids (La, Ce, Pr, Nd, Pm, Sm, Eu, Gd, Tb, Dy, Ho, Er, Tm, Yb, Lu), Hf, and Sc. Specifically, in a case where Y₂O₃ is mixed with ZrO₂ in the first insulating film 11, at least one layer of the switching element 10 may further include at least one element selected from the group consisting of lanthanoids (La, Ce, Pr, Nd, Pm, Sm, Eu, Gd, Tb, Dy, Ho, Er, Tm, Yb, Lu), Hf, and Sc.

In an example, the relationship 0.1≤A_Y/(A_Y+A_Ta)≤0.3 holds when “A_Y” is the mole percentage value (molar composition) of yttrium (Y) in the switching element 10 and “A_Ta” is the mole percentage value (molar composition) of tantalum (Ta) in the switching element 10. In other examples, other metallic elements other than yttrium and tantalum may be used in the switching element 10 and satisfy the same or a similar relationship.

As illustrated by FIG. 2, in the switching element 10, a barrier height Φ_{b2} of the first insulating film 11 is higher than a barrier height Φ_{b1} of each of the second insulating films 18a, 18B. Here, the barrier heights (Φ_{b2}, Φ_{b1}) are calculated using an electron affinity X, which is defined as a difference in energy (Ec) between a vacuum level and a conductor. The barrier height Φₘ of the switching element electrodes (19A, 19B) is calculated using a work function of the switching element electrodes (19A, 19B).

In general, any material can be used as the material of the second insulating films (18A, 18B), as long as the barrier height Φ_{b1} of the second insulating films (18A, 18B) is lower than the barrier height Φ_{b2} of the first insulating film 11. Specifically, as the material of the second insulating films (18A, 18B), tin oxide (SnO₂), zinc oxide (ZnO), indium oxide (In₂O₃), zinc sulfide (ZnS), or the like can be used.

As the material of the switching element electrodes 19A, 19B, tungsten (W), carbon (C), aluminum (Al), platinum (Pt), titanium (Ti), tungsten nitride (WN), titanium nitride (TiN), or the like can be used.

In an example, the ratio between the relative permittivity ε₁ of the first insulating film 11 and the relative permittivity ε₂ of the second insulating films 18A, 18B satisfies 2≤ε₁/ε₂≤3.5. With the ratio between the relative permittivity ε1 of the first insulating film 11 and the relative permittivity ε2 of the second insulating films (18A, 18B) set to satisfy 2≤ε1/ε2≤3.5, the switching element 10 can have a higher ON current and a lower OFF current.

### Operation of Switching Element

As illustrated in FIG. 3, the switching element 10 controls current by means of Fowler-Nordheim (FN) tunnel conduction. Namely, the current flows through a barrier with a barrier thickness d and a barrier height U. As illustrated in FIG. 2, the barrier height U is at a peak inside the first insulating film 11, and gradually decreases in the directions toward the second insulating films 18A, 18B and the switching element electrodes 19A, 19B.

### Effects of First Embodiment

In the nonvolatile semiconductor memory according to the first embodiment, the tunnel insulating films can be obtained by mixing Y₂O₃ with TiO₂, Ta₂O₅, and/or ZrO₂, whereby the insulation characteristic is significantly improved without adversely reducing the relative permittivity. Thus, with a tunnel barrier form having the peak barrier height at a center portion of the tunnel insulating films, improvement in current-voltage characteristic and in dielectric strength can be achieved.

### Modification of First Embodiment

### Configuration of Switching Element

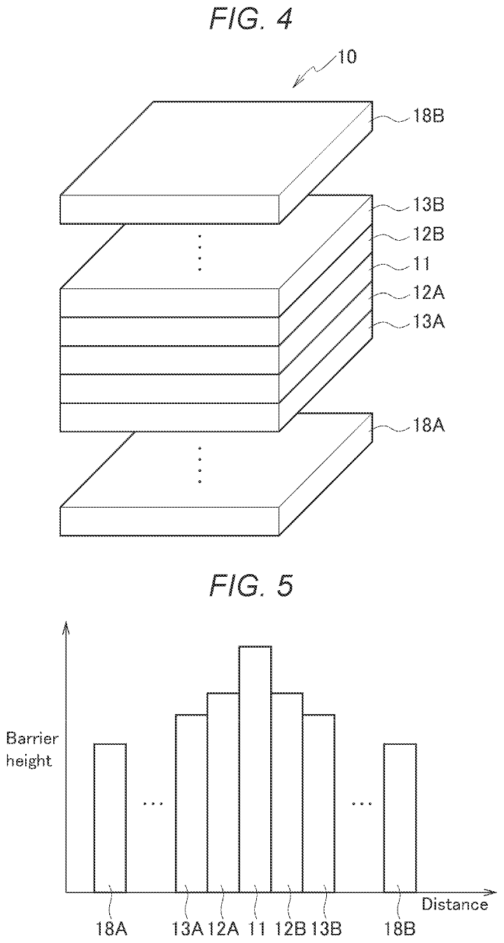

As illustrated in FIG. 4, a nonvolatile semiconductor memory 100A according to a modification of the first embodiment includes tunnel insulating films 11, 12A, 12B, 13A, 13B, . . . 18A, 18B, instead of just the tunnel insulating films 11, 18A, 18B according to the first embodiment. Namely, the total number of layers N of the tunnel insulating films is 2n+1 (here, n is a positive natural number). The other aspects are the same as those in the nonvolatile semiconductor memory 100 according to the first embodiment, and thus the description thereof will be omitted. The operation of the switching element 10 according to the modification of the first embodiment is the same as the operation of the switching element 10 according to the first embodiment, and thus the description thereof will be omitted.

The tunnel insulating films 11, 12A, 12B, 13A, 13B, . . . 18A, 18B include the first insulating films (11, 12A, 12B, 13A, 13B, . . . ) and the second insulating films (18A, 18B). The first insulating films (11, 12A, 12B, 13A, 13B, . . . ) may each include a plurality of layers.

### Composition of Switching Element

For example, the tunnel insulating films (11, 12A, 12B, 13A, 13B, . . . 18A, 18B) include along with Y and O along with at least one of Ta, Ti, and Zr.

It is noted that in the nonvolatile semiconductor memory 100A, at least one of the first insulating films (11, 12A, 12B, 13A, 13B, . . . ) and the second insulating films 18A, 18B of the switching element 10 may include Ta, O, and Y and/or at least one element selected from the group consisting of lanthanoids (La, Ce, Pr, Nd, Pm, Sm, Eu, Gd, Tb, Dy, Ho, Er, Tm, Yb, Lu), Hf, Zr, Sc, and Nb. Specifically, in a case where Y₂O₃ is added to Ta₂O₅ for the first insulating films (11, 12A, 12B, 13A, 13B, . . . ), at least one layer of the switching element 10 may include an element selected from the group consisting of Hf, Zr, Sc, Nb, and the lanthanoids (La, Ce, Pr, Nd, Pm, Sm, Eu, Gd, Tb, Dy, Ho, Er, Tm, Yb, Lu).

In the nonvolatile semiconductor memory 100A, at least one of the first insulating films (11, 12A, 12B, 13A, 13B, . . . ) and the second insulating films (18A, 18B) of the switching element may comprise Ti, O, and Y and/or at least one element selected from the group consisting of Hf, Zr, Sc, and the lanthanoids (La, Ce, Pr, Nd, Pm, Sm, Eu, Gd, Tb, Dy, Ho, Er, Tm, Yb, Lu). Specifically, in a case where Y₂O₃ is added to TiO₂ for the first insulating films (11, 12A, 12B, 13A, 13B, . . . ), at least one layer of the switching element 10 may include an element selected from the group consisting of lanthanoids (La, Ce, Pr, Nd, Pm, Sm, Eu, Gd, Tb, Dy, Ho, Er, Tm, Yb, Lu), Hf, Zr, and Sc.

In the nonvolatile semiconductor memory 100A, at least one of the first insulating films (11, 12A, 12B, 13A, 13B, . . . ) and the second insulating films (18A, 18B) may comprise Zr, O, and Y and/or at least one element selected from the group consisting of lanthanoids (La, Ce, Pr, Nd, Pm, Sm, Eu, Gd, Tb, Dy, Ho, Er, Tm, Yb, Lu), Hf, and Sc. Specifically, in a case where Y₂O₃ is mixed with ZrO₂ for the first insulating films (11, 12A, 12B, 13A, 13B, . . . ), at least one layer of the switching element 10 may further include at least one element selected from the group consisting of Hf, Sc, and lanthanoids (La, Ce, Pr, Nd, Pm, Sm, Eu, Gd, Tb, Dy, Ho, Er, Tm, Yb, Lu).

In an example, the relationship 0.1≤A_Y/(A_Y+A_Ta)≤0.3 holds when “A_Y” is the mole percentage value (molar composition) of yttrium (Y) in the switching element 10 and “A_Ta” is the mole percentage value of tantalum (Ta) in the switching element 10. In other examples, other metallic elements other than yttrium and tantalum may be used in the switching element 10 and satisfy the same or a similar relationship.

As illustrated in FIG. 5, in the switching element 10, the first insulating film 11 has the highest barrier height. The barrier height of the first insulating films (12A, 12B) is higher than the barrier height of the first insulating films (13A, 13B). The barrier heights of the first insulating films (11, 12A, 12B, 13A, 13B, . . . ) are higher than the barrier height of the second insulating films (18A, 18B).

As the materials of the first insulating films (11, 12A, 12B, 13A, 13B, . . . ), Y₂O₃ is added to Ta₂O₅, TiO₂, and/or ZrO₂ in such a way as to make the barrier height highest in the first insulating film 11 and gradually decrease therefrom. For example, the concentration of Y₂O₃ may be gradually changed layer-to-layer to make the barrier height highest in the first insulating film 11 but gradually decrease in the first insulating films (12A, 12B, 13A, 13B).

### Effects of Modification of First Embodiment

In the nonvolatile semiconductor memory according to the modification of the first embodiment, the tunnel insulating films are obtained by adding Y₂O₃ to TiO₂, Ta₂O₅, and/or ZrO₂, whereby the insulation characteristic of the base oxide material can be significantly improved without significantly reducing the relative permittivity. Thus, with a tunnel barrier having the peak barrier height at a center portion of the tunnel insulating films, improvement in current-voltage characteristic and in dielectric strength can be achieved.

### Second Embodiment

### Composition of Switching Element

While the tunnel insulating films according to the first embodiment comprise at least one of Ta, Ti, and Zr while also including Y and O, tunnel insulating films in a nonvolatile semiconductor memory 100B according to a second embodiment comprise at least one of Ta, Ti, and Zr while also including tungsten (W) and O. The other configurations and aspects are otherwise the same as those in the nonvolatile semiconductor memory 100 according to the first embodiment, and thus the description thereof will be omitted. The operation of the switching element 10 according to the second embodiment is also the same as the operation of the switching element 10 according to the first embodiment, and thus the description thereof will be omitted.

In an example, tungsten oxide (WO₃) is added to TiO₂, Ta₂O₅, or ZrO₂ and used for the first insulating film 11.

It is noted that in the nonvolatile semiconductor memory 100B, at least one of the first insulating film 11 and the second insulating films (18A, 18B) of the switching element 10 may comprise Ta, O, and W with at least one element selected from the group consisting of molybdenum (Mo) and chromium (Cr). For example, when WO₃ is added to Ta₂O₅ for the first insulating film 11, at least one layer of the switching element 10 may comprise at least one element selected from the group consisting of vanadium (V), Nb, Mo, and Cr.

In the nonvolatile semiconductor memory 100B, at least one of the first insulating film 11 and the second insulating films (18A, 18B) of the switching element 10 may comprise Ti, O, and W and/or at least one element selected from the group consisting of V, Nb, Mo, and Cr. For example, when WO₃ is added to TiO₂ for the first insulating film 11, at least one layer of the switching element 10 may further comprise at least one element selected from the group consisting of V, Nb, Mo, and Cr.

In the nonvolatile semiconductor memory 100B, for example, at least one layer of the first insulating film 11 and the second insulating films (18A, 18B) may comprise Zr, O, and W and/or at least one element selected from the group consisting of V, Nb, Mo, and Cr. For example, when WO₃ is added to ZrO₂ for the first insulating film 11, at least one layer of the switching element 10 may further comprise at least one element selected from the group consisting of V, Nb, Mo, and Cr.

In an example, the relationship 0.02≤A_W/(A_W+A_Ta)≤0.06 is satisfied when “A_W” is the mole percentage value (molar composition) of tungsten (W) in the switching element 10 and “A_Ta” is the mole percentage value of tantalum (Ta) in the switching element 10. In other examples, other metallic elements other than tungsten and tantalum may be used in the switching element 10 and satisfy the same or similar relationship.

### Effects of Second Embodiment

In the nonvolatile semiconductor memory according to the second embodiment, the tunnel insulating films are obtained by adding WO₃ to TiO₂, Ta₂O₅, and/or ZrO₂, whereby the insulation characteristic is significantly improved without significantly reducing the relative permittivity. Thus, with a tunnel barrier having a peak barrier height at a center portion of the tunnel insulating films, improvement in current-voltage characteristic and in dielectric strength can be achieved.

### Modification of Second Embodiment

### Configuration of Switching Element

A nonvolatile semiconductor memory 100C according to a modification of the second embodiment includes tunnel insulating films (11, 12A, 12B, 13A, 13B, . . . 18A, 18B), instead of the tunnel insulating films (11, 18A, 18B) according to the second embodiment. Namely, the total number of layers N of the tunnel insulating films (11, 12A, 12B, 13A, 13B, . . . 18A, 18B) is 2n+1 (where n is a positive natural number) The other configurations and aspects are the same as those in the nonvolatile semiconductor memory 100B according to the second embodiment, and thus the description thereof will be omitted.

The tunnel insulating films (11, 12A, 12B, 13A, 13B, . . . 18A, 18B) include the first insulating films (11, 12A, 12B, 13A, 13B, . . . ) and the second insulating films (18A, 18B).

### Composition of Switching Element

For example, the tunnel insulating films (11, 12A, 12B, 13A, 13B, . . . 18A, 18B) include at least one of Ta, Ti, and Zr and also includes W and O.

It is noted that in the nonvolatile semiconductor memory 100C, for example, at least one layer of the first insulating films (11, 12A, 12B, 13A, 13B, . . . ) and the second insulating films (18A, 18B) of the switching element 10 may comprise Ta, O, and W and/or at least one element selected from the group consisting of molybdenum (Mo) and chromium (Cr). For example, when WO₃ is added to Ta₂O₅ for the first insulating film 11, at least one layer of the switching element 10 may further include at least one element selected from the group consisting of V, Nb, Mo, and Cr.

It is to be noted that in the nonvolatile semiconductor memory 100C, at least one of the first insulating films (11, 12A, 12B, 13A, 13B, . . . ) and the second insulating films (18A, 18B) of the switching element 10 may comprise Ti, O, and W and/or at least one element selected from the group consisting of vanadium (V), Nb, Mo, and Cr. For example, when WO₃ is added to TiO₂ for the first insulating film 11, at least one layer of the switching element 10 may further comprise at least one element selected from the group consisting of V, Nb, Mo, and Cr.

In the nonvolatile semiconductor memory 100B, at least one layer of the first insulating films (11, 12A, 12B, 13A, 13B, . . . ) and the second insulating films (18A, 18B) of the switching element 10 may comprise Zr, O, and W and/or at least one element selected from the group consisting of V, Nb, Mo, and Cr. For example, when WO₃ is added to ZrO₂ for the first insulating film 11, at least one layer of the switching element 10 may comprise at least one element selected from the group consisting of V, Nb, Mo, and Cr.

In an example, the relationship 0.02≤A_W/(A_W+A_Ta)≤0.06 is satisfied when “A_W” is the mole percentage value of tungsten (W) in the switching element 10 and “A_Ta” is the mole percentage value of tantalum (Ta) in the switching element 10. In other examples, other metallic elements other than tungsten and tantalum may be used in the switching element 10 and satisfy the same or a similar relationship.

In the switching element 10, the first insulating film 11 has the highest barrier height. The barrier height of the first insulating films (12A, 12B) is higher than the barrier height of the first insulating films (13A, 13B). The barrier heights of the first insulating films (11, 12A, 12B, 13A, 13B, . . . ) are higher than the barrier height of the second insulating films (18A, 18B).

For example, for the first insulating films (11, 12A, 12B, 13A, 13B, . . . ), WO₃ can be added to Ta₂O₅, TiO₂, and/or ZrO₂ in such a manner as to make the barrier height highest in the first insulating film 11 and gradually decrease therefrom. In an example, the concentration of WO₃ may be gradually changed to make the barrier height highest in the first insulating film 11, then gradually decrease in the first insulating films (12A, 12B, 13A, 13B).

### Effects of Modification of Second Embodiment

In the nonvolatile semiconductor memory according to the modification of the second embodiment described above, the tunnel insulating films are obtained by adding WO₃ to TiO₂, Ta₂O₅, and/or ZrO₂, whereby the insulation characteristic is significantly improved without significantly reducing the relative permittivity. Thus, with a tunnel barrier form having the peak barrier height at a center portion of the tunnel insulating films, improvement in current-voltage characteristic and in dielectric strength can be achieved.

### Third Embodiment

### Composition of Switching Element

While the tunnel insulating films according to the first embodiment include at least one of Ta, Ti, and Zr along with Y and O, tunnel insulating films in a nonvolatile semiconductor memory 100D according to a third embodiment include at least one of Ta, Ti, and Zr along with Y, W, and O. The other configurations and aspects are the same as those in the nonvolatile semiconductor memory 100 according to the first embodiment, and thus the description thereof will be omitted.

In an example, the first insulating film 11 comprises Y₂O₃ and WO₃ added to TiO₂, Ta₂O₅, and/or ZrO₂.

It is noted that in the nonvolatile semiconductor memory 100D, at least one of the first insulating film 11 and the second insulating films (18A, 18B) of the switching element 10 may include Ta, O, and Y and/or at least one element selected from the group consisting of Hf, Zr, Sc, Nb, and lanthanoids (La, Ce, Pr, Nd, Pm, Sm, Eu, Gd, Tb, Dy, Ho, Er, Tm, Yb, Lu) Nb. In the nonvolatile semiconductor memory 100D, at least one layer of the first insulating film 11 and the second insulating films (18A, 18B) of the switching element 10 may include W and/or at least one element selected from the group consisting of Mo and Cr. Specifically, for example, in a case where Y₂O₃ and WO₃ are added Ta₂O₅ for the first insulating film 11, at least one layer of the switching element 10 may comprise Ta, O, and Y and/or at least one element selected from the group consisting of Hf, Zr, Sc, Nb, and lanthanoids (La, Ce, Pr, Nd, Pm, Sm, Eu, Gd, Tb, Dy, Ho, Er, Tm, Yb, Lu). When Y₂O₃ and WO₃ are added Ta₂O₅ for the first insulating film 11, at least one layer of the switching element 10 may further include W or at least one element selected from the group consisting of Mo and Cr.

In the nonvolatile semiconductor memory 100D, at least one of the first insulating film 11 and the second insulating films (18A, 18B) of the switching element 10 may comprise Ti, O, and Y and/or at least one element selected from the group consisting of Hf, Zr, Sc, and lanthanoids (La, Ce, Pr, Nd, Pm, Sm, Eu, Gd, Tb, Dy, Ho, Er, Tm, Yb, Lu) Sc. In the nonvolatile semiconductor memory 100D, for example, at least one layer of the first insulating film 11 and the second insulating films (18A, 18B) of the switching element 10 may comprise W or at least one element selected from the group consisting of V, Nb, Mo, and Cr. Specifically, in an example where Y₂O₃ and WO₃ are added to TiO₂ for the first insulating film 11, at least one layer of the switching element 10 may include at least one element selected from the group consisting of lanthanoids (La, Ce, Pr, Nd, Pm, Sm, Eu, Gd, Tb, Dy, Ho, Er, Tm, Yb, Lu), Hf, Zr, and Sc. When Y₂O₃ and WO₃ are added to TiO₂ for the first insulating film 11, at least one layer of the switching element 10 may include at least one element selected from the group consisting of V, Nb, Mo, and Cr.

In the nonvolatile semiconductor memory 100D, at least one of the first insulating film 11 and the second insulating films (18A, 18B) of the switching element 10 may include Zr, O, and Y and/or at least one element selected from the group consisting of lanthanoids (La, Ce, Pr, Nd, Pm, Sm, Eu, Gd, Tb, Dy, Ho, Er, Tm, Yb, Lu), Hf, and Sc. In the nonvolatile semiconductor memory 100D, at least one layer of the first insulating film 11 and the second insulating films (18A, 18B) of the switching element 10 may include W or at least one element selected from the group consisting of V, Nb, Mo, and Cr. Specifically, in an example where Y₂O₃ and WO₃ are added to ZrO₂ for the first insulating film 11, at least one layer of the switching element 10 may include at least one element selected from the group consisting of lanthanoids (La, Ce, Pr, Nd, Pm, Sm, Eu, Gd, Tb, Dy, Ho, Er, Tm, Yb, Lu), Hf, and Sc. When Y₂O₃ and WO₃ are added to ZrO₂ for the first insulating film 11, at least one layer of the switching element 10 may include at least one element selected from the group consisting of V, Nb, Mo, and Cr.

In an example, the relationship 0.1≤A_Y/(A_Y+A_Ta)≤0.3 is satisfied when “A_Y” is the mole percentage value of yttrium (Y) in the switching element 10 and “A_Ta” is the mole percentage value of tantalum (Ta) in the switching element 10. In an example, the relationship 0.02≤A_W/(A_W+A_Ta)≤0.06 is satisfied when “A_W” is the mole percentage value of tungsten (W) in the switching element 10 and “A_Ta” is the mole percentage value of tantalum (Ta) in the switching element 10. In other examples, other metallic elements other than tungsten and tantalum may be used in the switching element 10 and satisfy the same or a similar relationship.

### Effects of Third Embodiment

In the nonvolatile semiconductor memory according to the third embodiment, the tunnel insulating films are obtained by adding Y₂O₃ and WO₃ to TiO₂, Ta₂O₅, and/or ZrO₂, whereby the insulation characteristic is significantly improved without significantly reducing the relative permittivity. Thus, with a tunnel barrier form having the peak barrier height at a center portion of the tunnel insulating films, improvement in current-voltage characteristic and in dielectric strength can be achieved.

### Modification of Third Embodiment

### Configuration of Switching Element

A nonvolatile semiconductor memory 100E according to a modification of the third embodiment includes tunnel insulating films (11, 12A, 12B, 13A, 13B, . . . 18A, 18B), instead of the tunnel insulating films (11, 18A, 18B) according to the third embodiment. For example, the number of layers N of the tunnel insulating films (11, 12A, 12B, 13A, 13B, . . . 18A, 18B) is 2n+1 (where n is a natural number). The other configurations and aspects are the same as those in the nonvolatile semiconductor memory 100D according to the third embodiment, and thus the description thereof will be omitted.

The tunnel insulating films (11, 12A, 12B, 13A, 13B, . . . 18A, 18B) include the first insulating films (11, 12A, 12B, 13A, 13B, . . . ) and the second insulating films (18A, 18B).

### Composition of Switching Element

For example, the tunnel insulating films (11, 12A, 12B, 13A, 13B, . . . 18A, 18B) include at least one of Ta, Ti, and Zr, and also include Y, W, and O.

It is noted that in the nonvolatile semiconductor memory 100E, at least one layer of the first insulating films (11, 12A, 12B, 13A, 13B, . . . ) and the second insulating films (18A, 18B) of the switching element 10 may comprise Ta, O, and Y and/or at least one element selected from the group consisting of Hf, Zr, Sc, Nb, and lanthanoids (La, Ce, Pr, Nd, Pm, Sm, Eu, Gd, Tb, Dy, Ho, Er, Tm, Yb, Lu). In the nonvolatile semiconductor memory 100D, at least one of the first insulating films (11, 12A, 12B, 13A, 13B, . . . ) and the second insulating films (18A, 18B) of the switching element 10 may comprise W and/or at least one element selected from the group consisting of Mo and Cr. Specifically, in an example where Y₂O₃ and WO₃ are added to Ta₂O₅ for the first insulating film 11, at least one layer of the switching element 10 may comprise Ta, O, and Y and/or at least one element selected from the group consisting of lanthanoids (La, Ce, Pr, Nd, Pm, Sm, Eu, Gd, Tb, Dy, Ho, Er, Tm, Yb, Lu), Hf, Zr, Sc, and Nb. When Y₂O₃ and WO₃ is added Ta₂O₅ for the first insulating film 11, at least one layer of the switching element 10 may include W and/or at least one element selected from the group consisting of Mo and Cr.

In the nonvolatile semiconductor memory 100E, at least one layer of the first insulating films (11, 12A, 12B, 13A, 13B, . . . ) and the second insulating films (18A, 18B) may comprise Ti, O, and Y and/or at least one element selected from the group consisting of lanthanoids (La, Ce, Pr, Nd, Pm, Sm, Eu, Gd, Tb, Dy, Ho, Er, Tm, Yb, Lu), Hf, Zr, and Sc. In the nonvolatile semiconductor memory 100D, at least one layer of the switching element 10 may comprise W and/or at least one element selected from the group consisting of V, Nb, Mo, and Cr. Specifically, in an example where Y₂O₃ and WO₃ are added to TiO₂ for the first insulating film 11, at least one of the first insulating films (11, 12A, 12B, 13A, 13B, . . . ) and the second insulating films (18A, 18B) of the switching element 10 may include at least one element selected from the group consisting of lanthanoids (La, Ce, Pr, Nd, Pm, Sm, Eu, Gd, Tb, Dy, Ho, Er, Tm, Yb, Lu), Hf, Zr, and Sc. When Y₂O₃ and WO₃ are added to TiO₂ for the first insulating film 11, at least one layer of the switching element 10 may include at least one element selected from the group consisting of V, Nb, Mo, and Cr.

In the nonvolatile semiconductor memory 100E, at least one of the first insulating films (11, 12A, 12B, 13A, 13B, . . . ) and the second insulating films (18A, 18B) of the switching element 10 may include Zr, O, and Y and/or at least one element selected from the group consisting of lanthanoids (La, Ce, Pr, Nd, Pm, Sm, Eu, Gd, Tb, Dy, Ho, Er, Tm, Yb, Lu), Hf, and Sc. In the nonvolatile semiconductor memory 100D, at least one of the first insulating films (11, 12A, 12B, 13A, 13B, . . . ) and the second insulating films (18A, 18B) of the switching element 10 may comprise W and/or at least one element selected from the group consisting of V, Nb, Mo, and Cr. Specifically, in an example where Y₂O₃ and WO₃ are added to ZrO₂ for the first insulating film 11, at least one layer of the switching element 10 may include at least one element selected from the group consisting of lanthanoids (La, Ce, Pr, Nd, Pm, Sm, Eu, Gd, Tb, Dy, Ho, Er, Tm, Yb, Lu), Hf, and Sc. When Y₂O₃ and WO₃ are added to ZrO₂ for the first insulating film 11, at least one layer of the switching element 10 may include at least one element selected from the group consisting of V, Nb, Mo, and Cr.

In an example, the relationship 0.1≤A_Y/(A_Y+A_Ta)≤0.3 is satisfied when “A_Y” is the mole percentage value of yttrium (Y) in the switching element 10 and “A_Ta” is the mole percentage value of tantalum (Ta) in the switching element 10. In an example, the relationship 0.02≤A_W/(A_W+A_Ta)≤0.06 is satisfied when “A_W” is the mole percentage value (molar composition) of tungsten (W) in the switching element 10 and “A_Ta” is the mole percentage value (molar composition) of tantalum (Ta) in the switching element 10.

In the switching element 10, the first insulating film 11 has the highest barrier height. The barrier height of the first insulating films (12A, 12B) is higher than the barrier height of the first insulating films (13A, 13B). The barrier heights of the first insulating films (11, 12A, 12B, 13A, 13B, . . . ) are higher than the barrier height of the second insulating films (18A, 18B).

In an example, the first insulating films (11, 12A, 12B, 13A, 13B, . . . ) can comprise Y₂O₃ and WO₃ added to Ta₂O₅, TiO₂, and/or ZrO₂ to make the barrier height highest in the first insulating film 11 and gradually decrease therefrom. For example, the concentrations of Y₂O₃ and WO₃ added may be gradually changed to make the barrier height highest in the first insulating film 11 and gradually decrease in the first insulating films (12A, 12B, 13A, 13B).

### Effects of Modification of Third Embodiment

In the nonvolatile semiconductor memory according to the modification of the third embodiment, the tunnel insulating films are obtained by adding Y₂O₃ and WO₃ to TiO₂, Ta₂O₅, and/or ZrO₂, whereby the insulation characteristic is significantly improved without significantly reducing the relative permittivity. Thus, with a tunnel barrier having the peak barrier height at a center portion of the tunnel insulating films, improvement in current-voltage characteristic and in dielectric strength can be achieved.

### Nonvolatile Semiconductor Memory Device

A configuration of a nonvolatile semiconductor memory device incorporating a nonvolatile semiconductor memory 100 will be described.

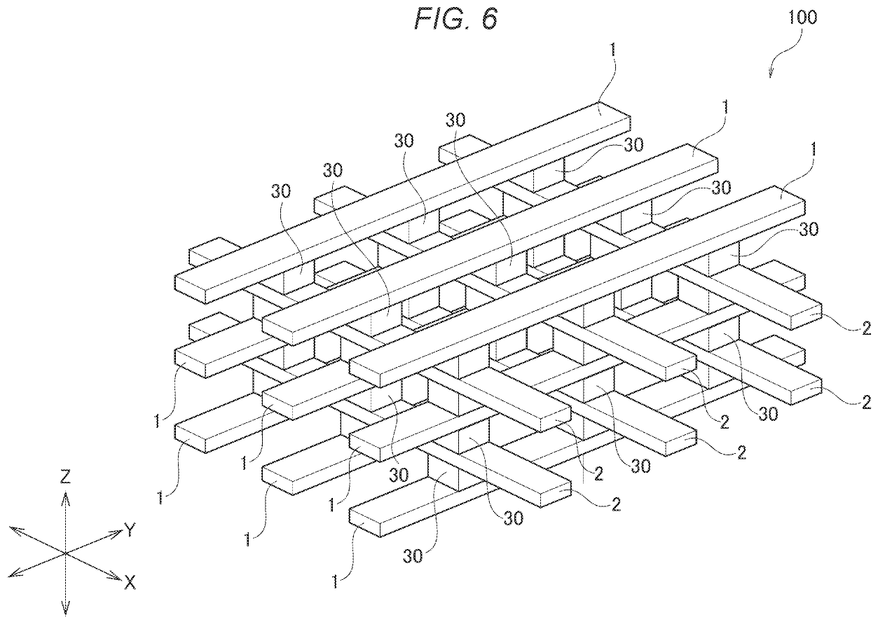

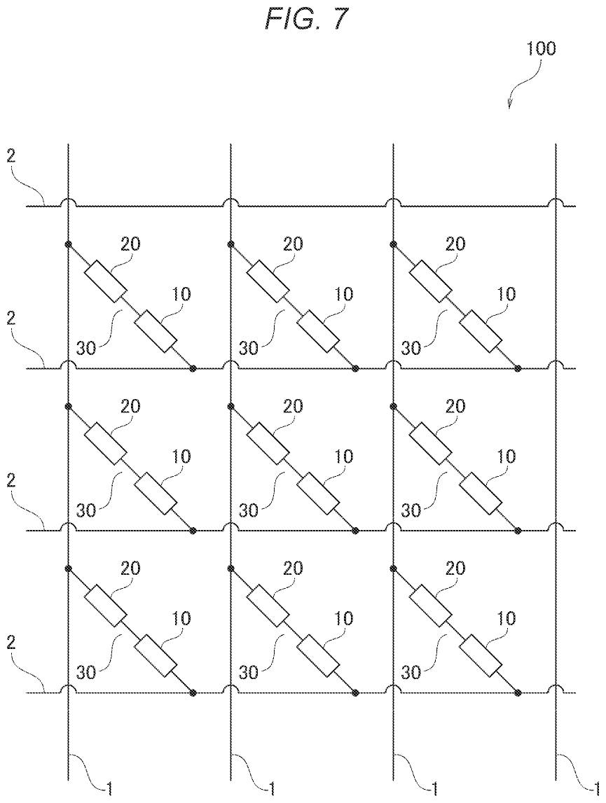

FIG. 6 illustrates a configuration in which a plurality of layers of the nonvolatile semiconductor memory 100 are stacked. In the structure depicted, four layers of the nonvolatile semiconductor memory 100 are stacked. FIG. 7 is an equivalent circuit diagram of one layer part of the nonvolatile semiconductor memory device incorporating the nonvolatile semiconductor memory 100.

The nonvolatile semiconductor memories according to the first to the third embodiments are applicable to the depicted semiconductor memory device.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A nonvolatile semiconductor memory, comprising:
a first electrode;
a second electrode spaced from the first electrode; and
a memory element and a switching element between the first electrode and the second electrode, wherein
the switching element includes a tunnel insulating film, and
the tunnel insulating film includes at least one of tantalum, titanium, and zirconium, and further includes yttrium and oxygen.

2. The nonvolatile semiconductor memory according to claim 1, wherein the tunnel insulating film includes a first insulating film and a second insulating film.

3. The nonvolatile semiconductor memory according to claim 2, wherein the first insulating film comprises a plurality of layers.

4. The nonvolatile semiconductor memory according to claim 1, wherein the relationship 0.1≤A_Y/(A_Y+A_Ta)≤0.3 is satisfied, when A_Y is the molar composition of yttrium in the switching element and A_Ta is the molar composition of tantalum in the switching element.

5. The nonvolatile semiconductor memory according to claim 1, wherein
the tunnel insulating film includes a first insulating film and a second insulating film, and
at least one of the first insulating film and the second insulating film comprises Ta, O, Y, and at least one element selected from the group consisting of Hf, Zr, Sc, Nb, La, Ce, Pr, Nd, Pm, Sm, Eu, Gd, Tb, Dy, Ho, Er, Tm, Yb, and Lu.

6. The nonvolatile semiconductor memory according to claim 1, wherein
the tunnel insulating film includes a first insulating film and a second insulating film, and
at least one of the first insulating film and the second insulating film comprises Ti, O, Y, and at least one element selected from the group consisting of Hf, Zr, Sc, La, Ce, Pr, Nd, Pm, Sm, Eu, Gd, Tb, Dy, Ho, Er, Tm, Yb, and Lu.

7. The nonvolatile semiconductor memory according to claim 1, wherein
the tunnel insulating film includes a first insulating film and a second insulating film, and
at least one of the first insulating film and the second insulating film comprises Zr, O, Y, and at least one element selected from the group consisting of Hf, Sc, and La, Ce, Pr, Nd, Pm, Sm, Eu, Gd, Tb, Dy, Ho, Er, Tm, Yb, and Lu.

8. A nonvolatile semiconductor memory, comprising:
a first electrode;
a second electrode spaced from the first electrode; and
a memory element and a switching element in series between the first electrode and the second electrode, wherein
the switching element includes a tunnel insulating film, and
the tunnel insulating film includes at least one of tantalum, titanium, and zirconium, and further includes tungsten and oxygen.

9. The nonvolatile semiconductor memory according to claim 8, wherein the tunnel insulating film includes a first insulating film and a second insulating film.

10. The nonvolatile semiconductor memory according to claim 8, wherein the relationship 0.02≤A_W/(A_W+A_Ta)≤0.06 is satisfied, when A_W is the molar composition of tungsten in the switching element and A_Ta is the molar composition of tantalum in the switching element.

11. The nonvolatile semiconductor memory according to claim 8, wherein
the tunnel insulating film includes a first insulating film and a second insulating film, and
at least one of the first insulating film and the second insulating film comprises Ta, O, W, and at least one of Mo and Cr.

12. The nonvolatile semiconductor memory according to claim 8, wherein
the tunnel insulating film includes a first insulating film and a second insulating film, and
at least one of the first insulating film and the second insulating film comprises Ti, O, W, and at least one element selected from the group consisting of V, Nb, Mo, and Cr.

13. The nonvolatile semiconductor memory according to claim 8, wherein
the tunnel insulating film includes a first insulating film and a second insulating film, and
at least one of the first insulating film and the second insulating film comprises Zr, O, W, and at least one element selected from the group consisting of V, Nb, Mo, and Cr.

14. A nonvolatile semiconductor memory, comprising:
a first electrode;
a second electrode spaced from the first electrode; and
a memory element and a switching element in series between the first electrode and the second electrode, wherein
the switching element includes a tunnel insulating film, and
the tunnel insulating film comprises yttrium, tungsten, oxygen, and at least one of tantalum, titanium, and zirconium O.

15. The nonvolatile semiconductor memory according to claim 14, wherein
the tunnel insulating film includes a first insulating film and a second insulating film, and
the first insulating film comprises a plurality of layers.

16. The nonvolatile semiconductor memory according to claim 14, wherein the relationships 0.1≤A_Y/(A_Y+A_Ta)≤0.3 and 0.02≤A_W/(A_W+A_Ta)≤0.06 are satisfied, where A_Y is the molar composition of yttrium in the switching element, A_W is the molar composition of tungsten in the switching element, and A_Ta is the molar composition of tantalum in the switching element.

17. The nonvolatile semiconductor memory according to claim 14, wherein
the tunnel insulating film includes a first insulating film and a second insulating film, and
at least one of the first insulating film and the second insulating film comprises Ta, O, Y, W and at least one element selected from the group consisting of Hf, Zr, Sc, Nb, La, Ce, Pr, Nd, Pm, Sm, Eu, Gd, Tb, Dy, Ho, Er, Tm, Yb, Lu, or at least one of Mo and Cr.

18. The nonvolatile semiconductor memory according to claim 14, wherein
the tunnel insulating film includes a first insulating film and a second insulating film, and
at least one of the first insulating film and the second insulating film comprises Ti, O, Y, W or any element selected from the group consisting of La, Ce, Pr, Nd, Pm, Sm, Eu, Gd, Tb, Dy, Ho, Er, Tm, Yb, Lu), Hf, Zr, Sc, Nb Mo, and Cr.

19. The nonvolatile semiconductor memory according to claim 14, wherein
the tunnel insulating film includes a first insulating film and a second insulating film, and
at least one of the first insulating film and the second insulating film includes Zr, O, and Y and an element selected from the group consisting of La, Ce, Pr, Nd, Pm, Sm, Eu, Gd, Tb, Dy, Ho, Er, Tm, Yb, Lu, Hf, Zr, Sc, Nb, W, Mo, and Cr.

20. The nonvolatile semiconductor memory according to claim 14, wherein the memory element includes a variable resistance element, a magnetoresistive element, or a phase change element.
